(19) United States
(12) Patent Application Publication
(10) Pub. No.: US 2006/0057815 A1
(43) Pub. Date: Mar. 16, 2006

(54) Method of manufacturing a semiconductor device

(75) Inventor: Myoung-Soo Kim, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/212,237

(22) Filed: Aug. 26, 2005

(30) Foreign Application Priority Data
Sep. 16, 2004 (KR) 2004-74095

(51) Int. Cl. H01L 21/76

(52) U.S. Cl. 438/401; 438/424; 438/975; 438/427

(57) ABSTRACT

In a method of manufacturing a high-voltage semiconductor device, a mask layer is formed on a semiconductor substrate. The mask layer is patterned to form a stepped portion of the mask layer. A photoresist pattern for defining an active region of the substrate is formed on the substrate using the stepped portion as an alignment mark. The alignment mark for aligning the photoresist pattern that is used for the active region of the high-voltage semiconductor device may be formed by reduced processing steps with reduced incidence of contamination, thereby improving device performance with higher productivity and reduced production costs.

### CROSS REFERENCE TO RELATED APPLICATION

This application claims priority to Korean Patent Application No. 2004-74095, filed on Sep. 16, 2004, the content of which is hereby incorporated by reference in its entirety.

### BACKGROUND OF THE INVENTION

1. Field of the Invention

The present invention relates to a method of manufacturing a semiconductor device. More particularly, the present invention relates to a method of manufacturing a high-voltage semiconductor device that is used for a liquid crystal display-driving integrated circuit.

2. Description of the Related Art

A semiconductor device such as a liquid crystal display (LCD) driving integrated circuit to which a high voltage is applied includes a high voltage-resistant device that is capable of resisting about 15V to about 120V. To form the high voltage-resistant device, before an active region of a semiconductor substrate is formed, impurities are implanted into the semiconductor substrate. A well drive-in process is performed on the semiconductor substrate to form a deep well of the semiconductor substrate.

Generally, in the process for forming the deep well, a stepped portion is not formed; therefore, after forming the well, it is very difficult to align the active region in a photolithography process for defining the active region of the semiconductor substrate. However, one method of forming an alignment mark that is used for defining an active region in the process of forming a deep well is disclosed in Korean Patent Laid Open Publication No. 2003-59949.

FIGS. 1 to 10 are cross-sectional views illustrating the conventional method of manufacturing a semiconductor device that is disclosed in the Korean Patent Laid Open Publication. Referring to FIG. 1, a pad oxide layer 12 is formed on a semiconductor substrate 10 having a device region and a scribe lane region such as a P type silicon substrate. Phosphorus (P⁺) ions as an N type dopant are implanted into the semiconductor substrate 10 having the pad oxide layer 12 at an acceleration voltage of about 1.8 MeV at a dosage of about 5.0×10¹²/cm³ to form an N type well 14.

Referring to FIG. 2, a first silicon nitride layer 16 is formed on the pad oxide layer 12 to form an ion implantation mask that is used for a P type well of the semiconductor substrate 10 doped with the phosphorous ions,. Referring to FIG. 3, a first photoresist pattern 18 is formed on the first silicon nitride layer 16. The first silicon nitride layer 16 is partially etched using the first photoresist pattern 18 as an etching mask to form a first ion implantation mask 16a. The first ion implantation mask 16a exposes a portion of the scribe lane region, and a portion of the pad oxide layer 12 in a first region in which the P type well is to be formed. Boron (B⁺) ions as a P type dopant are implanted into the semiconductor substrate 10 having the first ion implantation mask 16a at an acceleration voltage of about 500 KeV at a dosage of about 8.0×10¹²/cm³. The boron ions are implanted into the exposed portions of the scribe lane region and the first region.

Referring to FIG. 4, the first photoresist pattern 18 and the exposed portions of the pad oxide layer 12 are removed to expose the portion of the scribe lane region and the semiconductor substrate 10 in the first region through the first ion implantation mask 16a. The exposed portions of the scribe lane region and the semiconductor substrate 10 are oxidized under an oxygen atmosphere to form a first oxide layer 20 on the exposed portions of the scribe lane region and the semiconductor substrate 10. Preferably, the first oxide layer 20 has a thickness of about 1,000 Å.

In general, in a process for forming an oxide layer by an oxidation process, the oxide layer grows upwardly and downwardly from a surface of the semiconductor substrate 10. As a result, the oxide layer has an upper portion thickness and a lower portion thickness measured from the surface of the semiconductor substrate 10. The ratio of thickness of the upper portion to the lower portion is about 56:44. Thus, when the first oxide layer 20 has a thickness of about 1,000 Å, the first oxide layer 20 has an upper portion thickness of about 560 Å and a lower portion thickness of about 440 Å. As a result, the distance between the surface of the semiconductor substrate and a lowermost position of the first oxide layer 20 is about 440 Å.

A well drive-in process is carried out on the semiconductor 10 at a temperature of about 1,100° C. for a period of time of 13 hours to diffuse the P type dopant from the first region into the semiconductor substrate 10, thereby forming the P type well 24. The P type well 24 has a junction depth of about 1 μm to about 12 μm from the surface of the semiconductor substrate 10.

Referring to FIG. 5, the first oxide layer 20 is partially removed by a wet etching process using the first ion implantation mask as an etching mask. A buffered oxide etchant (BOE) is used in the wet etching process. As a result, a first remaining oxide layer 20a having a thickness of about 150 Å is formed on the exposed portions of the scribe lane region and the semiconductor substrate 10. As shown in FIG. 5, after the first oxide layer 20 is partially removed, recesses having depths ΔS1 from the surface of the semiconductor substrate 10 are formed at a surface portion of the semiconductor substrate to form preliminary stepped portions at the scribe lane region and in the first region of the semiconductor substrate 10. The depths ΔS1 of the recesses are substantially identical to each other.

Referring to FIG. 6, the first remaining oxide layer 20a and the first ion implantation mask 16a on the preliminary stepped portions are covered with a second silicon nitride layer 26. A second photoresist pattern 28 is then formed on the second silicon nitride layer 26. The second photoresist pattern 28 exposes a portion of the scribe lane region and a portion of the second silicon nitride layer 26 in a second region of the semiconductor substrate 10 in which a P type pocket well is to be formed.

Referring to FIG. 7, the second silicon nitride layer 26 and the first ion implantation mask 16a are sequentially etched using the second photoresist pattern 28 as an etching mask to form first and second ion implantation mask patterns 16b and 26a. The second ion implantation mask pattern 26a exposes a portion of the first remaining oxide layer 20a that covers the stepped portion of the semiconductor substrate 10 in the scribe lane region, and a portion of the pad oxide layer 12 in the second region where the P type pocket well is to be formed. Boron (B⁺) ions as a P type dopant are implanted into the semiconductor substrate 10 having the second ion implantation mask pattern 26a at an acceleration voltage of about 300 KeV at a dosage of about 4.0×10¹²/cm³. The boron ions are implanted into the exposed portions of the scribe lane region and the second region of the semiconductor substrate 10.

Referring to FIG. 8, the second photoresist pattern 28, and the exposed portions of the pad oxide layer 12 and the first remaining oxide layer 20a that covers the stepped portion of the semiconductor substrate 10 in the scribe lane region are removed to expose the stepped portion in the scribe lane region and a portion of the semiconductor substrate 10 in the second region where the P type pocket well is to be formed. The exposed portions of the scribe lane region and the semiconductor substrate 10 are oxidized under an oxygen atmosphere to form a second oxide layer 30 on the exposed portions of the scribe lane region and the semiconductor substrate 10. According to the present method, the first oxide layer 30 has a thickness of about 500 Å to about 5,000 Å, preferably 1,000 Å.

As described above, in a process for forming an oxide layer by an oxidation process in accordance with the method disclosed in Korean Patent Laid Open Publication No. 2003-59949, the ratio of thickness of the upper portion to the lower portion of the oxide layer is about 56:44. Thus, when the second oxide layer 30 has a thickness of about 1,000 Å, the first oxide layer 20 has an upper portion thickness of about 560 Å and a lower portion thickness of about 440 Å. As a result, the distance between the surface of the semiconductor substrate and a lowermost position of the second oxide layer 30 is about 440 Å.

A well drive-in process is carried out on the semiconductor 10 at a temperature of about 1,100° C. for a period of time of 13 hours to diffuse the P type dopant from the second region into the semiconductor substrate 10, thereby forming a P type pocket well 34. According to the present method, the P type pocket well 34 has a junction depth of about 1 μm to about 12 μm from the surface of the semiconductor substrate 10 that is shallower than that of the N type well 14.

Referring to FIG. 9, the second oxide layer 30, the second ion implantation mask pattern 26a, the first ion implantation mask pattern 16b, the first remaining oxide layer 20a and the pad oxide layer 12 are removed by a wet etching process using a buffered oxide etchant (BOE). As a result, a first recess having a depth ΔSk from the surface of the semiconductor substrate 10 is formed at a surface portion of the scribe lane region to form an alignment mark in the scribe lane region. A second recess having a depth ΔSpp from the surface of the semiconductor substrate 10 is formed in the first region to form a second stepped portion in the first region. Further, a third recess having a depth ΔSp from the surface of the semiconductor substrate 10 is formed in the second region to form a third stepped portion in the second region. According to the present method, the depths ΔSpp and ΔSp of the first and third recesses are shallower than the depth ΔSk of the second recess.

Referring to FIG. 10, a pad oxide layer 42 having a thickness of about 110 Å, a silicon nitride layer 44 having a thickness of about 1,500 Å, and an anti-reflective layer 46 having a thickness of about 260 Å are sequentially formed on the semiconductor substrate 10 having the first, second and third stepped portions. A third photoresist pattern 50 for defining an active region of the semiconductor substrate 10 is formed on the anti-reflective layer 46 using a stepped portion of the silicon nitride layer 44 above the first stepped portion as an alignment mark. That is, the first stepped portion functions as the alignment mark for aligning the third photoresist pattern 50. Additionally, an isolation layer is formed in the device region to define the active region of the semiconductor substrate 10.

However, the conventional method of forming the alignment mark that is used in the photolithography process for defining the active region on the semiconductor substrate is a complex process that includes numerous steps which results in a high manufacture cost. Further, after the isolation layer for defining the active region is formed, materials remain around peripheral portions of the stepped portions. Thus, to remove the remaining materials, an excessive chemical mechanical polishing (CMP) process or an additional etching process is required which increases process-generated particles and contaminants. However, it is desirable that particles and contaminants such as photoresist, photoresist residue, and residual etching reactants and byproducts be minimized to achieve improved device performance with higher productivity and reduced production costs.

### SUMMARY OF THE INVENTION

Exemplary embodiments of the present invention provide a method of manufacturing a semiconductor device that is capable of reducing the processing steps that affect the incidence of contamination, thereby improving device performance with higher productivity and reduced production costs.

In a method of manufacturing a high-voltage semiconductor device in accordance with an exemplary embodiment of the present invention, a mask layer is formed on a semiconductor substrate. The mask layer is patterned to form a stepped portion of the mask layer. A photoresist pattern for defining an active region of the substrate is formed on the substrate using the stepped portion as an alignment mark.

In a method of manufacturing a high-voltage semiconductor device in accordance with an exemplary embodiment of the present invention, first and second impurities are implanted into a device region of a substrate to form a first well. A mask layer is formed on the substrate having the first well. A first photoresist pattern is formed on the mask layer to partially expose a first region of the device region and a portion of the mask layer in a scribe lane region of the substrate through the first photoresist pattern. The mask layer is partially etched using the photoresist pattern as an etching mask for a first stepped portion of the mask layer in the first region and a second stepped portion of the mask layer in the scribe lane region. Third impurities that are a conductivity type substantially identical to that of the first impurities are implanted into the first region using the first photoresist pattern as an ion implantation mask to form a second well. The first photoresist pattern is then removed. A second photoresist pattern for defining an active region of the substrate is formed on the device region using the second stepped portion as an alignment mark.

According to at least one exemplary embodiment of the present invention, the alignment mark for aligning the photoresist pattern that is used for defining the active region of the high-voltage semiconductor device may be formed by reduced processing steps with reduced incidence of contamination, thereby improving device performance with higher productivity and reduced production costs.

### BRIEF DESCRIPTION OF THE DRAWINGS

The present invention will become more apparent to those of ordinary skill in the art when descriptions of exemplary embodiments thereof are read with reference to the accompanying drawings, of which:

FIGS. 1 to 10 are cross-sectional views illustrating a conventional method of manufacturing a high-voltage semiconductor device.

FIGS. 11 to 23 are cross-sectional views illustrating a method of manufacturing a high-voltage semiconductor device in accordance with exemplary embodiments of the present invention.

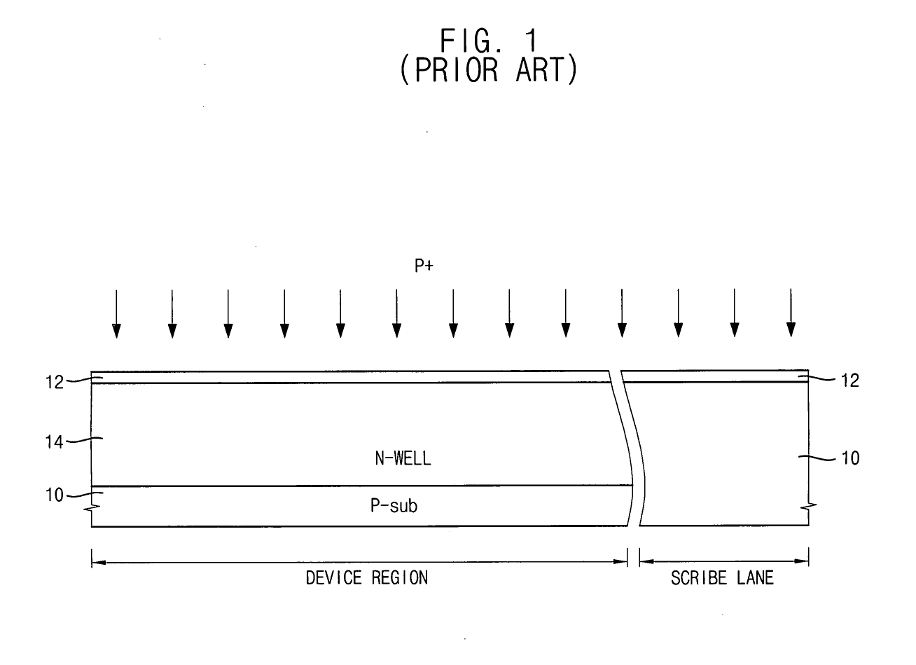

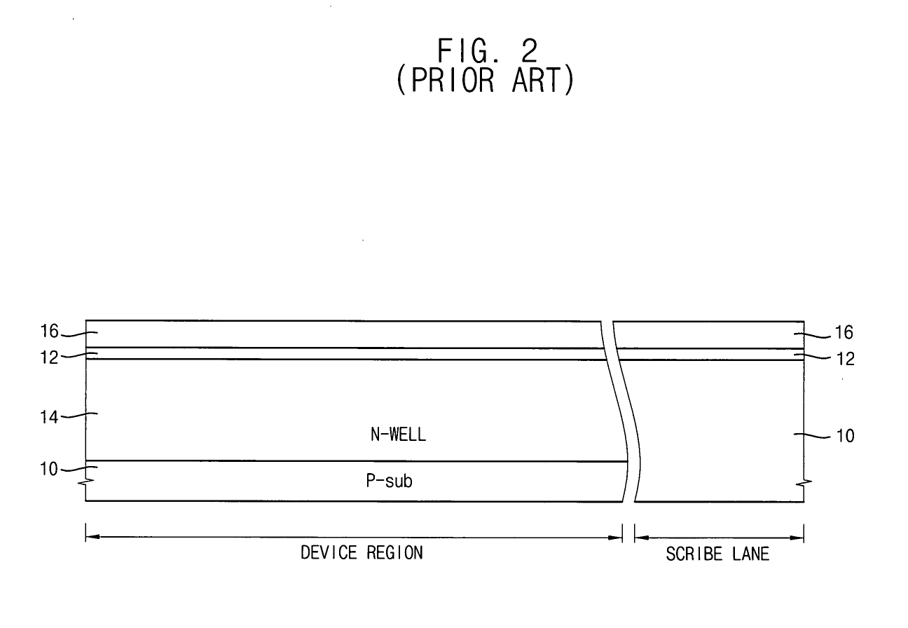

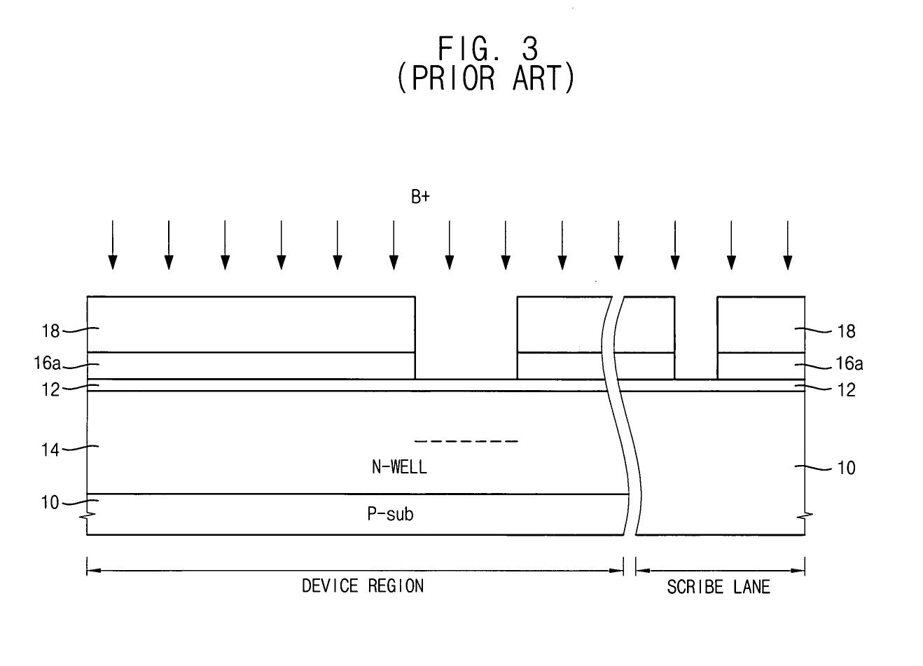

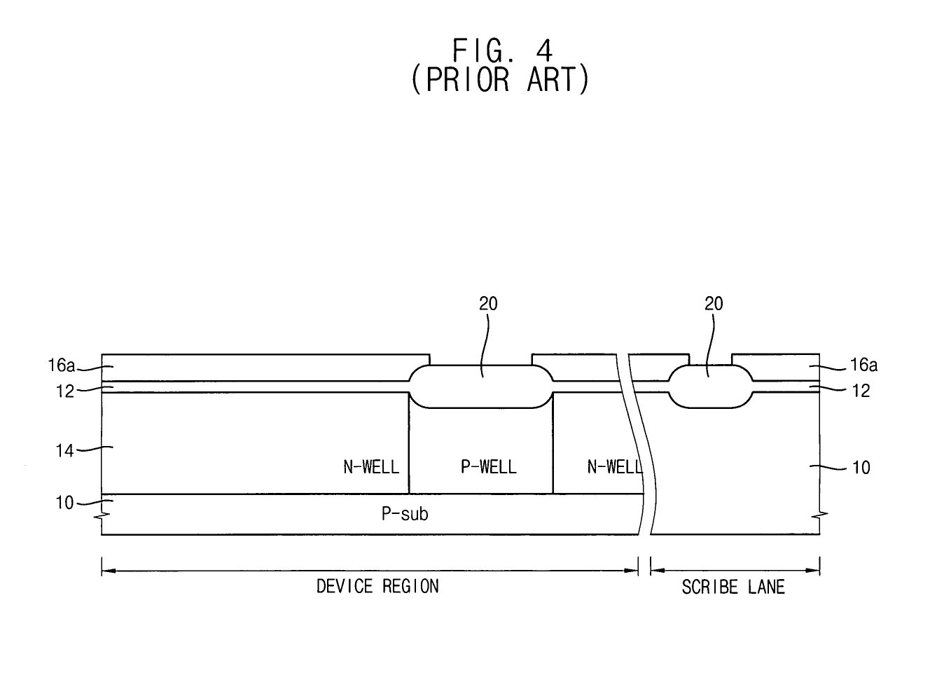

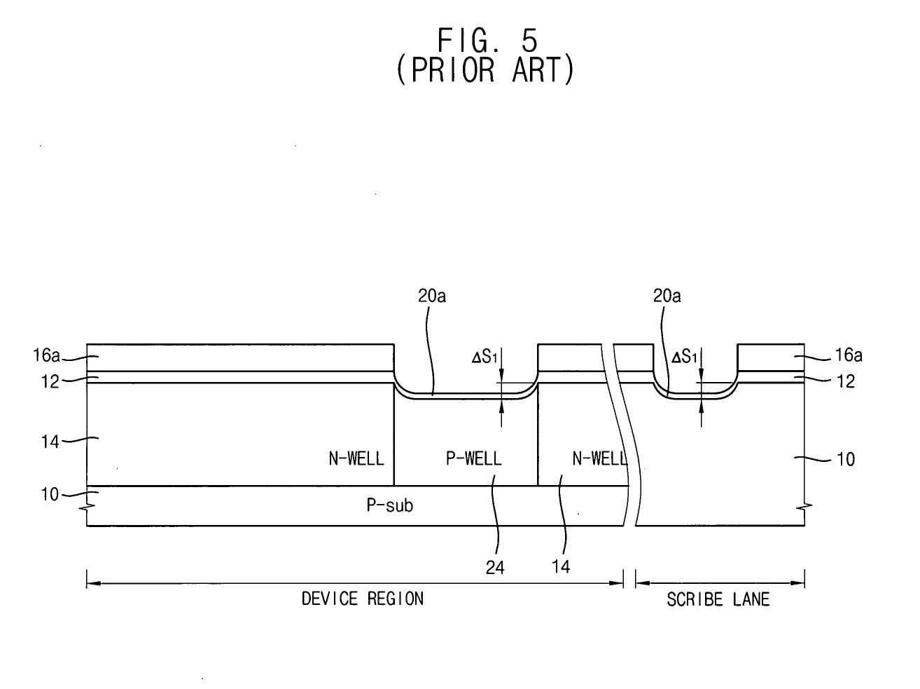

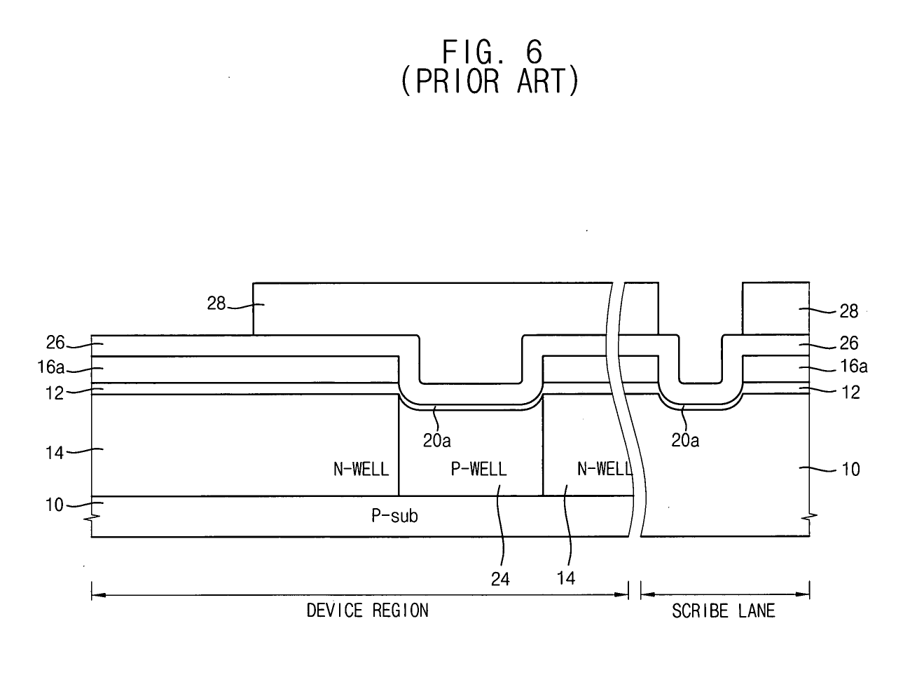

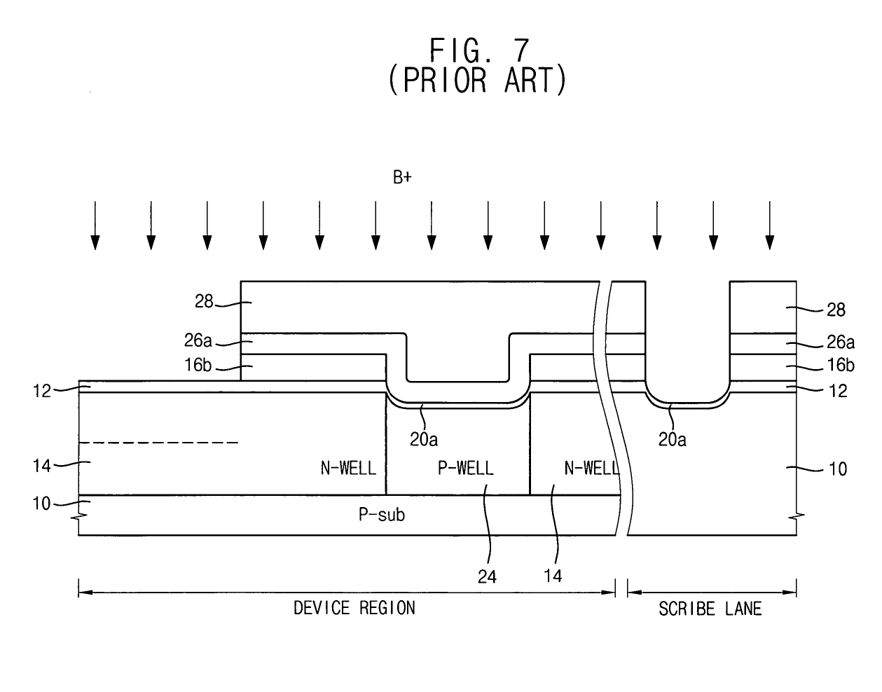

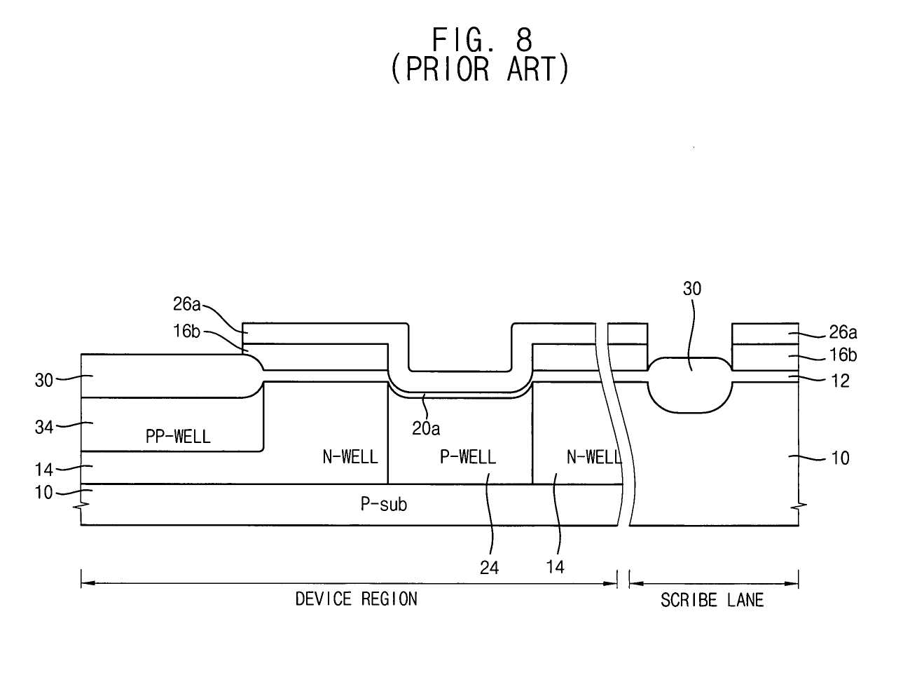

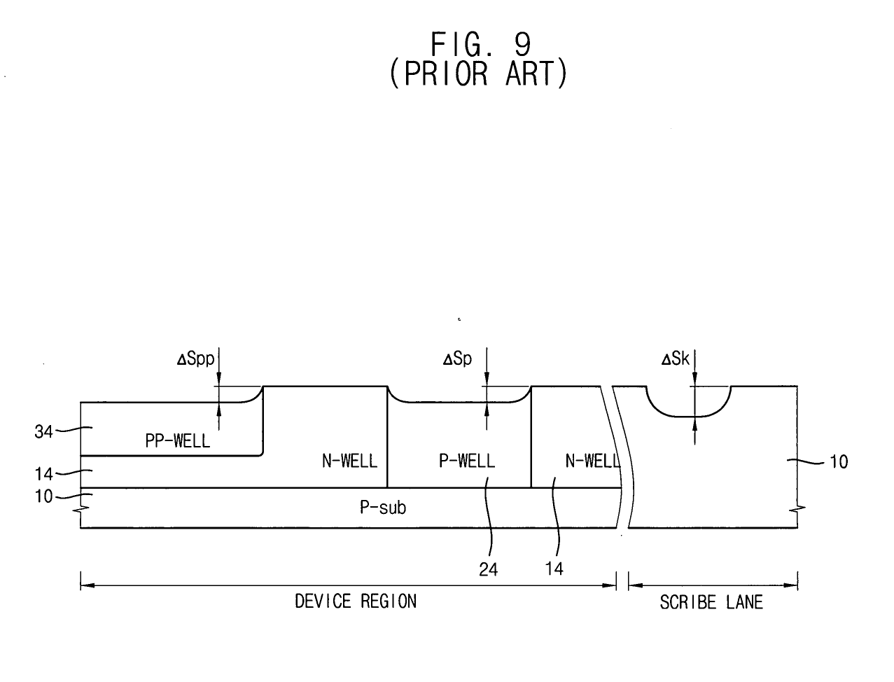

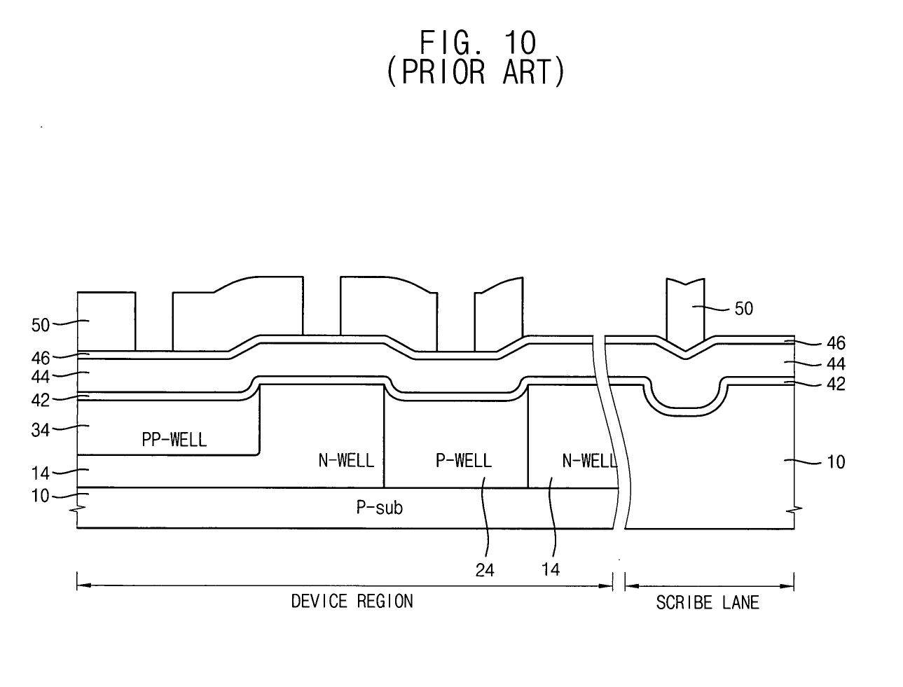

### DETAILED DESCRIPTION OF EXEMPLARY EMBODIMENTS

Hereinafter, the exemplary embodiments of the present invention will be described in detail with reference to the accompanying drawings. Like numbers refer to like elements throughout the description of the figures.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Semiconductor devices may vary in accordance with the kinds of impurities that are implanted into a semiconductor substrate. In at least one exemplary embodiment of the present invention, the impurities may include first conductivity type impurities, for example, boron, and second conductivity type impurities, for example, phosphorous.

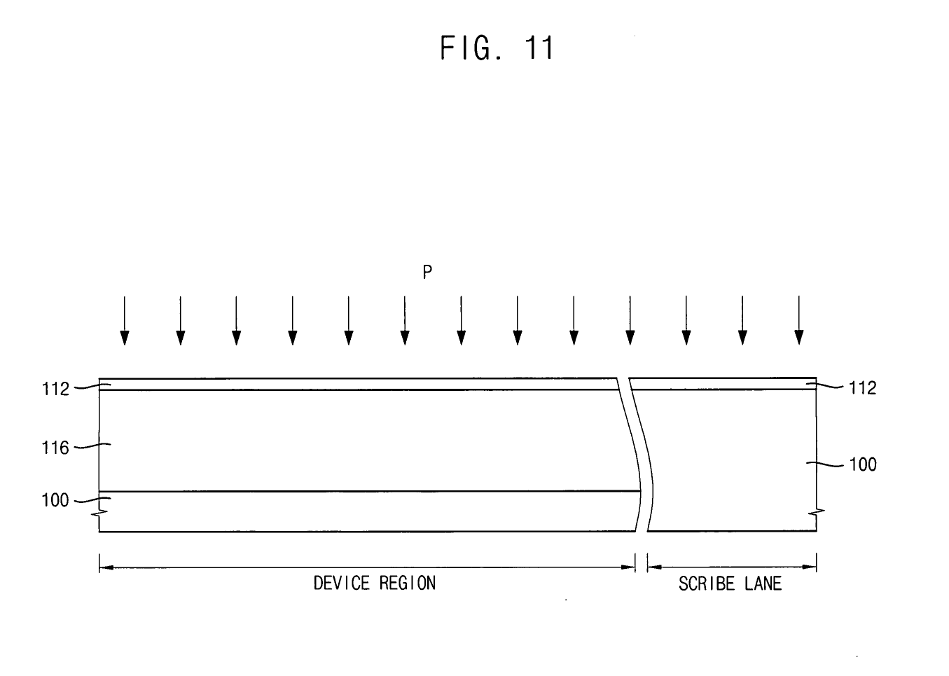

FIGS. 11 to 23 are cross-sectional views illustrating a method of manufacturing a high-voltage semiconductor device in accordance with an exemplary embodiment of the present invention. Referring to FIG. 11, a pad oxide layer 112 having a thickness of about 110 Å is formed on a semiconductor substrate 100 having a device region and a scribe lane region. For the purposes of this disclosure, the device region is defined as a region where electrical elements are formed. The semiconductor substrate may include a silicon substrate of a first conductivity type. Further, the pad oxide layer 112 may be formed by a rapid thermal oxidation process, a furnace thermal oxidation process, a plasma oxidation process, etc. For example, according to the rapid thermal oxidation process, a surface portion of the semiconductor substrate 100 is oxidized at a temperature of about 800° C. to about 950° C. under several pressures for a period of time from about 10 seconds to about 30 seconds to form the pad oxide layer 112 including silicon oxide.

First impurities of the second conductivity type, for example, phosphorous ions, are implanted into the semiconductor substrate 100 having the pad oxide layer 112 at an acceleration voltage of about 2.0 MeV at a dosage of about 5.0×10¹²/cm³ to form a first well 116 corresponding to an N type well.

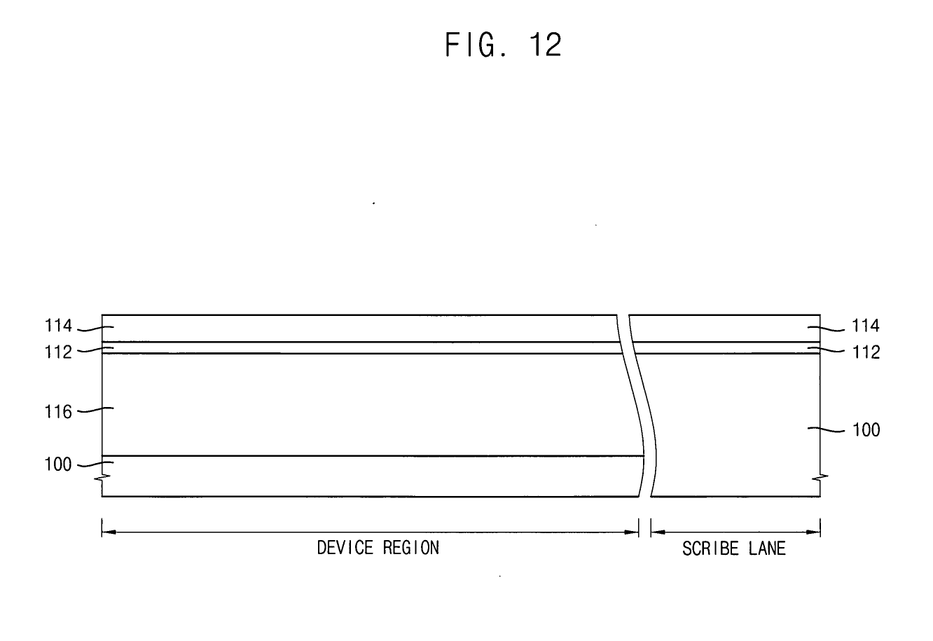

Referring to FIG. 12, a mask layer 114 having a thickness of about 300 Å to about 5,000 Å is formed on the pad oxide layer 112. In an exemplary embodiment of the present invention, the mask layer 114 has a thickness of about 1,000 Å. Silicon oxide may be deposited on the pad oxide layer 112 by a low pressure chemical vapor deposition (LPCVD) process to form the mask layer 114. It will be understood that any means for forming the pad oxide layer 112 should be suitable for implementing the invention. Here, since the mask layer 114 functions as a stepped portion for aligning a photoresist pattern that is used for an active region of the semiconductor substrate 100 and a hard mask layer for forming an isolation layer, it is necessary to properly determine the thickness of the mask layer 11 4.

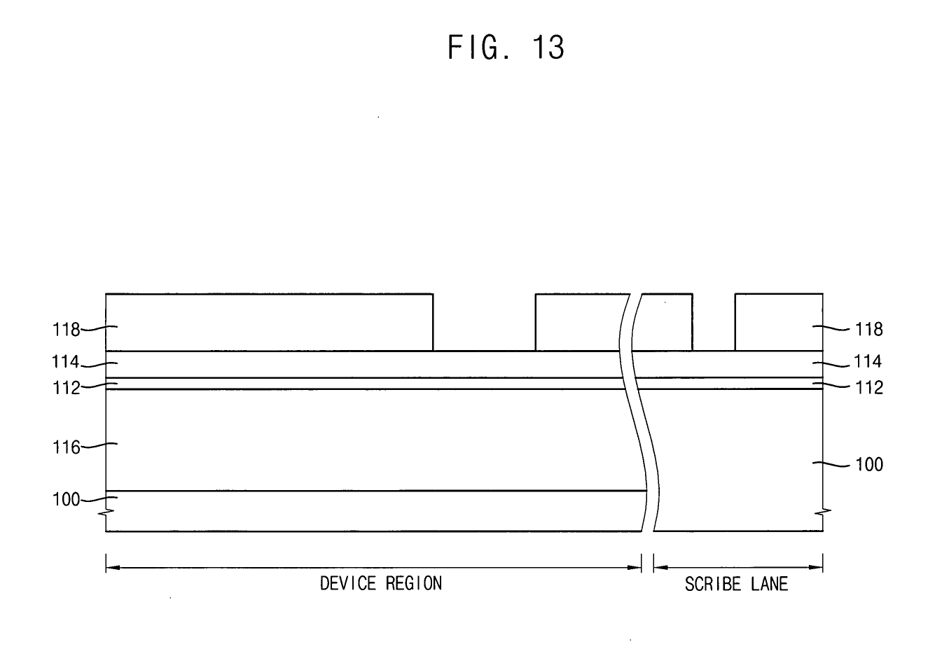

Referring to FIG. 13, a first photoresist pattern 118 is formed on the mask layer 114 to partially expose portions of the mask layer 114, which are positioned in a first region of the device region and in the scribe lane region, through the first photoresist pattern 118.

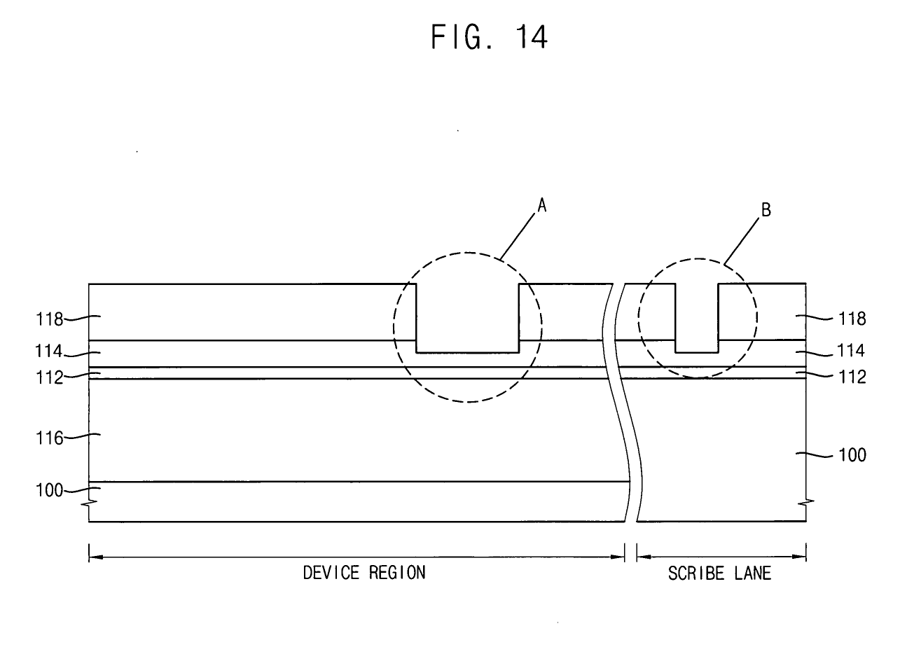

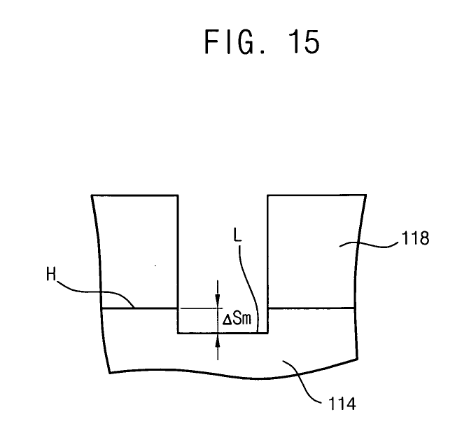

Referring to FIGS. 14 and 15, the mask layer 114 is partially etched using the first photoresist pattern 118 as an etching mask to form a mask pattern 114a. The mask pattern 114a includes a first stepped portion A of the mask pattern 114a in the first region of the device region and a second stepped portion B of the mask pattern 114a in the scribe lane region. As a result, a first recess is positioned in the first stepped portion A and a second recess is positioned in the second stepped portion B.

FIG. 15 shows an enlarged cross-sectional view illustrating the first stepped portion A and the second stepped portion B according to an exemplary embodiment of the present invention. Referring to FIG. 15, the first stepped portion A has a height Sm from a bottom face L of the first recess to a surface H of the mask pattern 114a in the first region of the device region. The second stepped portion B has the height Sm from a bottom face L of the second recess to a surface H of the mask pattern 114a in the scribe lane region. According to an exemplary embodiment of the present invention, a minimum height is no less than 200 Å for recognizing an alignment between a well region of the semiconductor substrate 100 and a photoresist pattern; therefore, the height Sm of the second stepped portion B from the bottom face L of the second recess to the surface H of the mask pattern 114a may be no less than 200 Å.

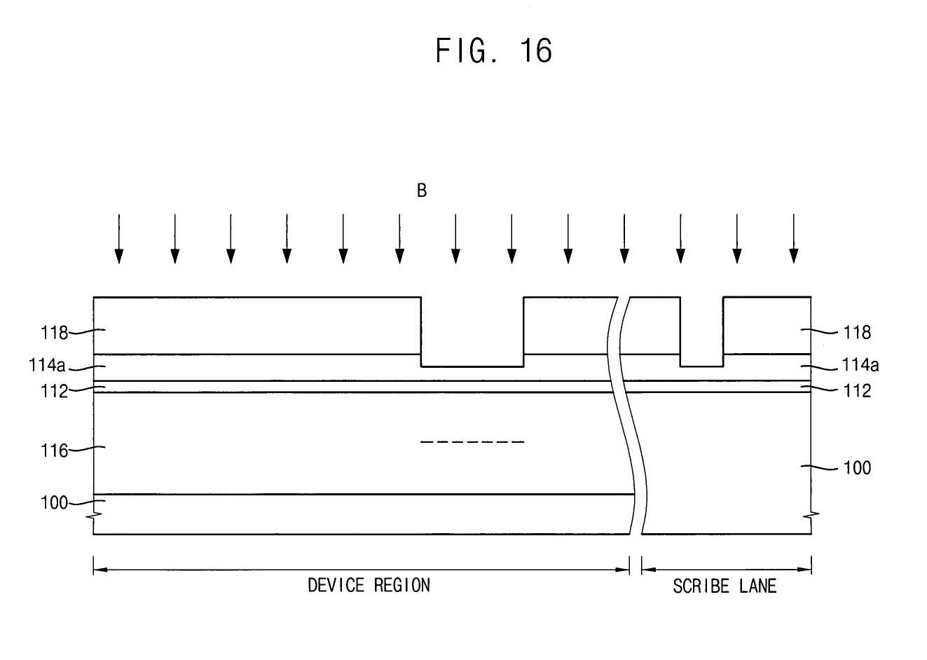

Referring to FIG. 16, according to an exemplary embodiment of the present invention, second impurities of the first conductivity type, for example, boron ions, are implanted into the first region of the device region and the scribe lane region using the first photoresist pattern 118 as an ion implantation mask at an acceleration voltage of about 70 KeV at a dosage of about 8.0×10¹²/cm³.

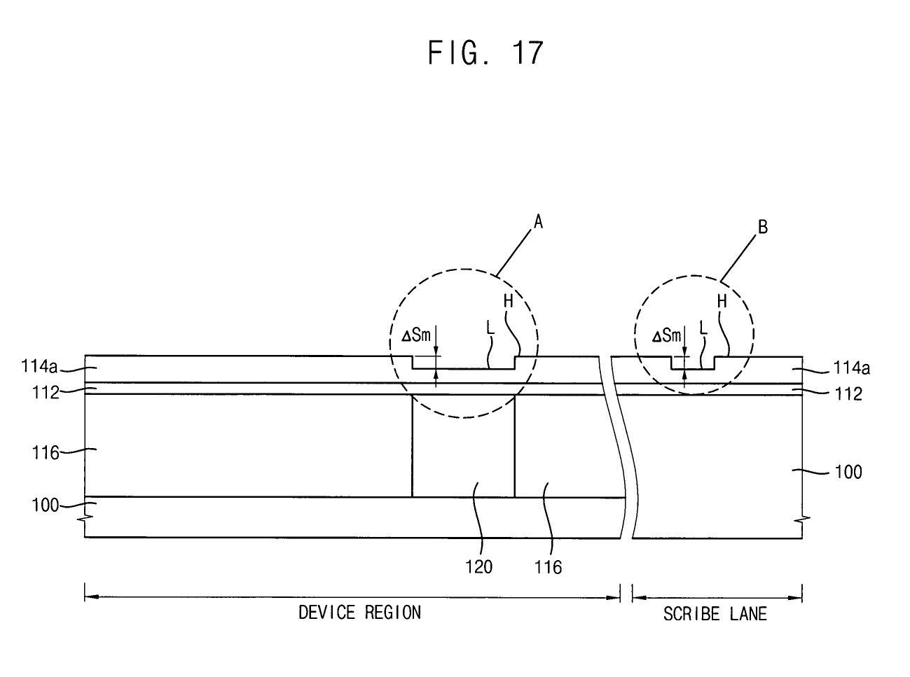

Referring to FIG. 17, the first photoresist pattern 118 is then removed to expose the first stepped portion A of the mask pattern 114a in the first region of the device region and a second stepped portion B of the mask pattern 114a in the scribe lane region.

As shown in FIGS. 15 and 17, the heights Sm of the first and second stepped portions A and B (the height difference between the upper surface H of the mask layer 114 and the lower surface L) may be equal or similar to each other.

The semiconductor substrate 100 is thermally treated to diffuse the second impurities of the first conductivity type into the semiconductor substrate 100. According to an exemplary embodiment of the present invention, the thermal treatment process may include a well drive-in process that is carried out at a temperature of about 1,100° C. under a nitrogen atmosphere for a period of time of about 13 hours. As a result, after the thermal treatment process is completed, a second well 120 corresponding to a P type well is formed in the first region of the device region. The second well 120 may have a junction depth of about 1 μm to about 12 μm from a surface of the semiconductor substrate 100.

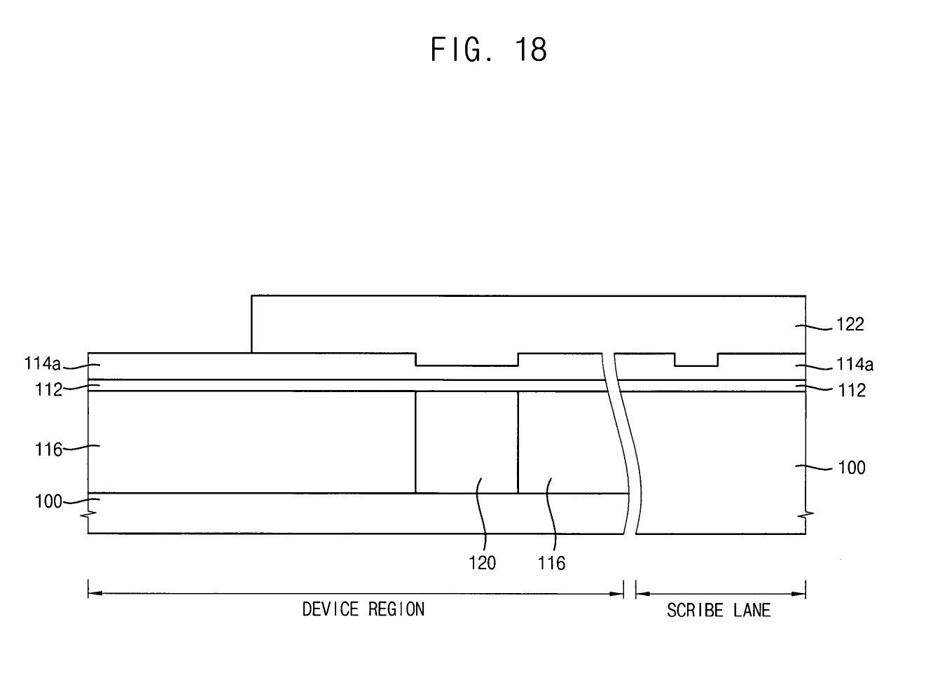

Referring to FIG. 18, a photoresist film (not shown) is formed on the mask pattern 114a to fill up the first and second stepped portions A and B. The photoresist film is exposed and developed using the second stepped portion B of the mask pattern 114a in the scribe lane region as an alignment mark to form a second photoresist pattern 122 partially exposing the mask pattern 114a in a second region of the device region.

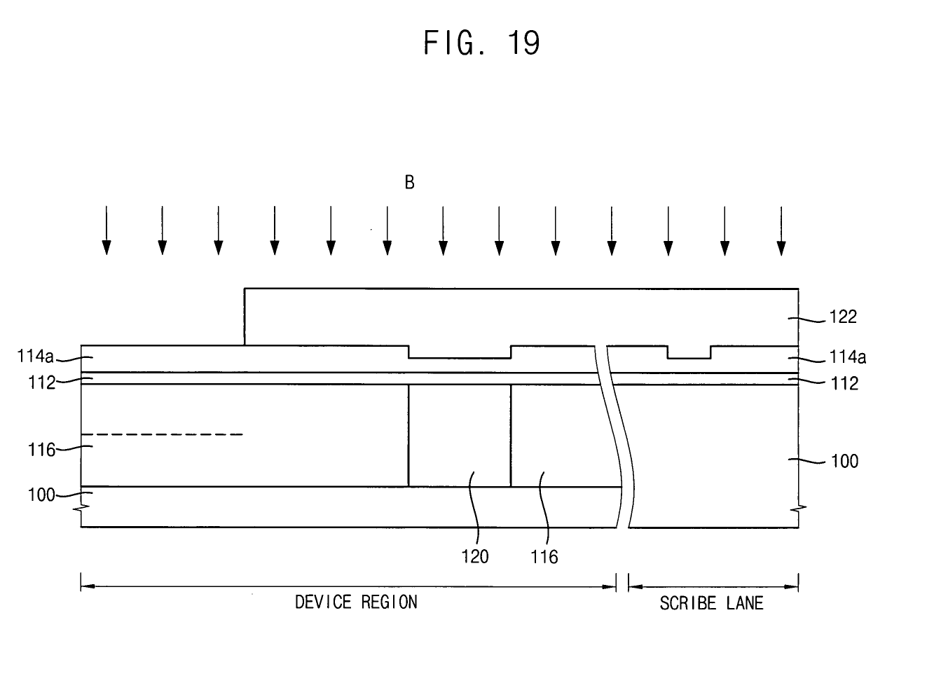

Referring to FIG. 19, third impurities of the first conductivity type, for example, boron ions, are implanted into the second region of the device region using the second photoresist pattern 122 as an ion implantation mask at an acceleration voltage of about 750 KeV at a dosage of about 8.0×10¹²/cm³.

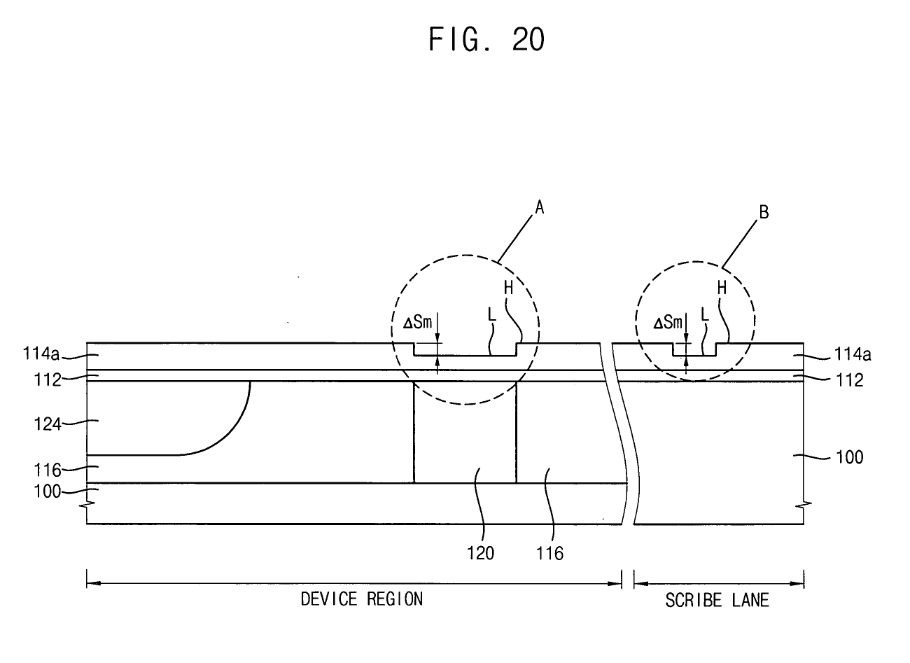

Referring to FIG. 20, the second photoresist pattern 122 is then removed. The semiconductor substrate 100 is thermally treated to diffuse the second impurities of the first conductivity type and implanted into the second region of the device region, into the semiconductor substrate 100. According to an exemplary embodiment of the present invention, the thermal treatment process may include a well drive-in process that is performed at a temperature of about 1,100° C. under a nitrogen atmosphere for a period of time of about 13 hours. As a result, when the thermal treatment process is completed, a third well 124 corresponding to a P type well is formed in the second region of the device region. Here, the third well 124 is referred to as a P type pocket well or a PP type well. Further, the third well 124 may have a junction depth of about 1 μm to about 12 μm that is shallower than that of the first well 116.

If the junction depth of the third well 124 is substantially identical to or deeper than that of the first well 116, the first and third wells 116 and 124 are electrically connected to each other. Hence, substantially identical voltages may be applied to the first and third wells 116 and 124 electrically connected to each other and the semiconductor device may malfunction.

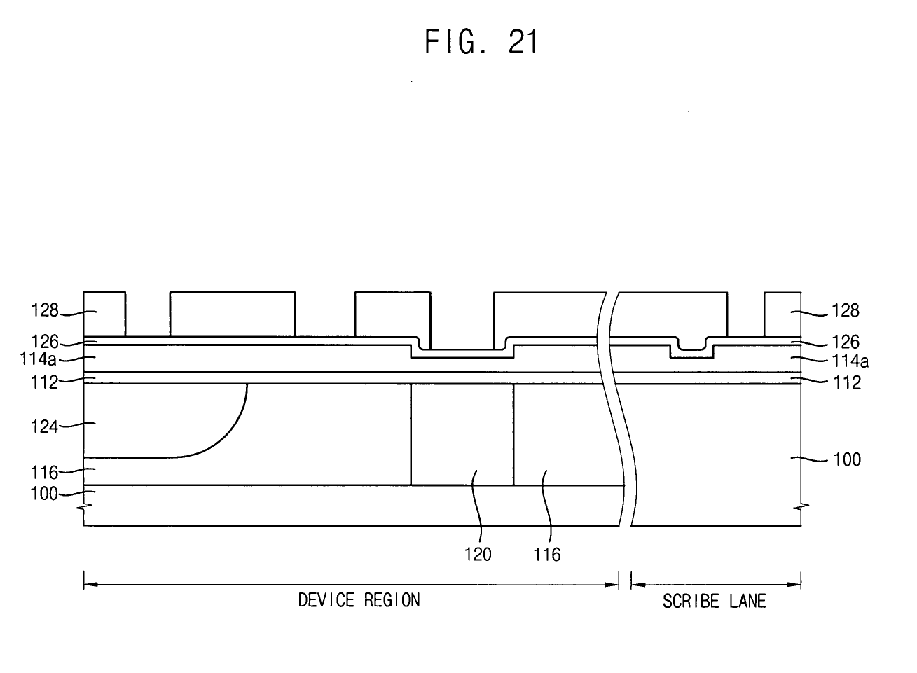

Referring to FIG. 21, an anti-reflective layer 126 is formed on the mask pattern 114a having the first and second stepped portions A and B. A photoresist film (not shown) is formed on the anti-reflective layer 126 to fill up the first and second stepped portions A and B.

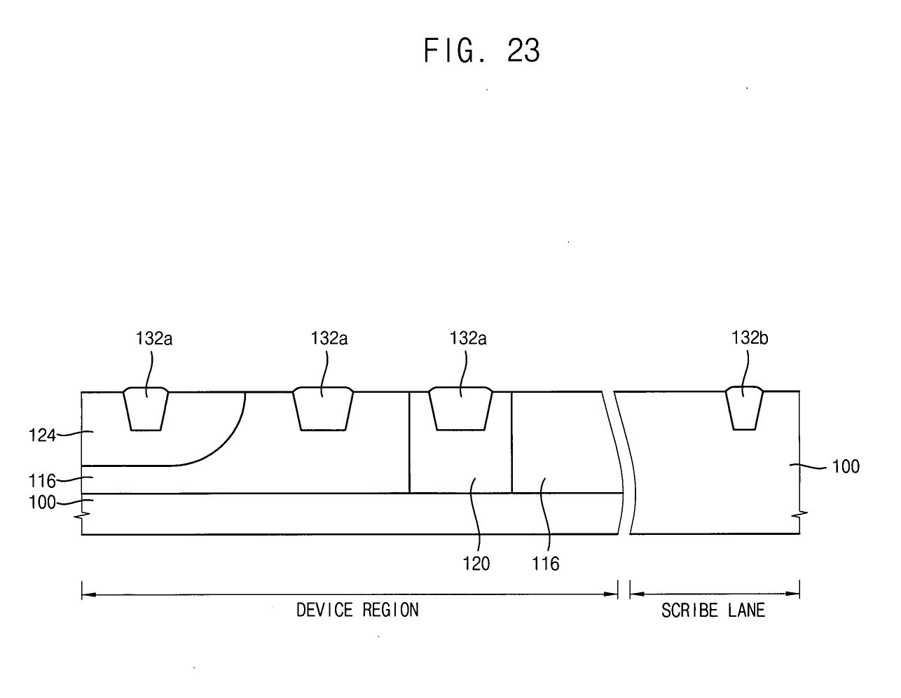

A third photoresist pattern 128 is formed on the device region and the scribe lane region of the semiconductor substrate 100 using the second stepped portion B of the mask pattern 114a in the scribe lane region as an alignment mark to partially expose an isolation region (see FIG. 23) where the isolation layer is formed and a surface of the anti-reflective layer 126 in a region where the alignment mark is formed. According to at least one exemplary embodiment of the present invention, the second stepped portion B in the scribe lane region provides a sufficient stepped portion that is used for accurately aligning the third photoresist pattern 128. Further, the mask pattern 114a functions as the hard mask layer for forming the isolation layer as well as the alignment mark that is capable of providing the stepped portion for aligning the third photoresist pattern 128.

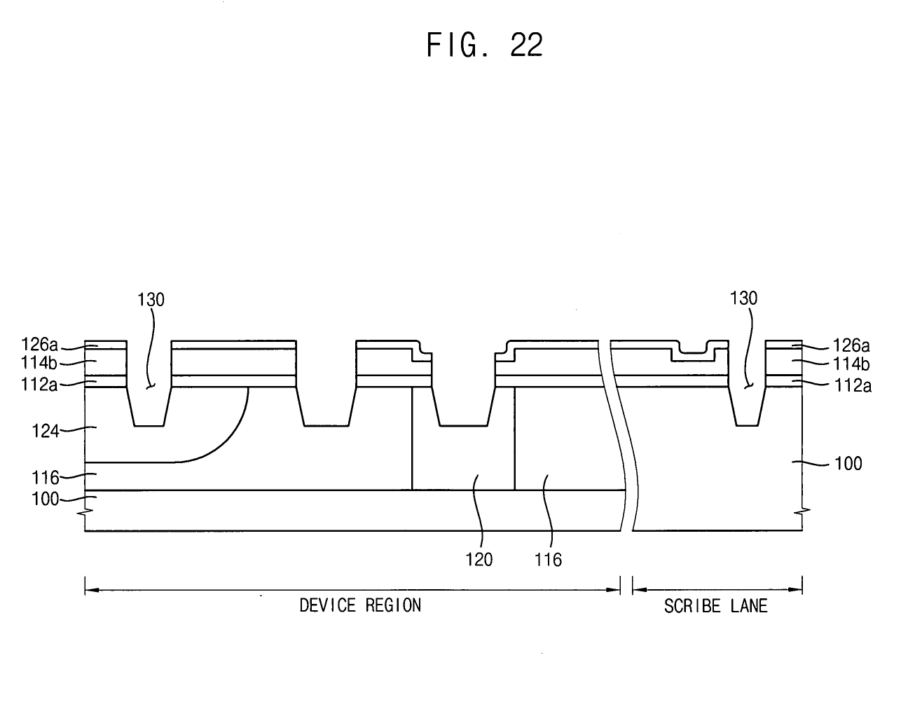

Referring to FIG. 22, the anti-reflective layer 126, the mask pattern 114a, the pad oxide layer 122 and the semiconductor substrate 100 are partially etched using the third photoresist pattern 128 as an etching mask to form trenches 130. Referring to FIG. 23, the third photoresist pattern 128 is then removed. An insulation layer (not shown) is formed on the mask pattern 114a to fill up the trenches 130. The insulation layer is planarized by a chemical mechanical polishing (CMP) process until the surface of the mask pattern 114a is exposed to form a preliminary isolation layer (not shown). The mask pattern 114a and the pad oxide layer 112 are then removed to form a first isolation layer 132a in the device region for defining the active region and a second isolation layer 132b in the scribe lane region. The second isolation layer 132b is used for an alignment mark for following processes.

According to an exemplary embodiment of the present invention, the stepped portions are not formed in the device region so that materials may not remain in the device region. As a result, an excessive CMP process or an additional etching process for removing the remaining materials may not be needed.

As described above, the mask layer functions as the hard mask layer for forming the isolation layers as well as the alignment mark for forming the photoresist pattern. Thus, according to at least one exemplary embodiments of the present invention, the alignment mark for aligning the photoresist pattern that is used for defining the active region of the high-voltage semiconductor device may be formed by reduced processing steps with reduced incidence of contamination, thereby improving device performance with higher productivity and reduced production costs.

Although the processes and apparatus of the present invention have been described in detail with reference to the accompanying drawings for the purpose of illustration, it is to be understood that the inventive processes and apparatus are not to be construed as limited thereby. It will be readily apparent to those of reasonable skill in the art that various modifications to the foregoing exemplary embodiments may be made without departing from the spirit and scope of the invention as defined by the appended claims.

What is claimed is:

1. A method of manufacturing a semiconductor device, comprising:
forming a mask layer on a substrate;
patterning the mask layer to form a stepped portion; and
forming a photoresist pattern for forming an active region of the substrate using the stepped portion as an alignment mark.

2. The method of claim 1, wherein the mask layer comprises silicon nitride.

3. The method of claim 1, wherein the mask layer is formed to a thickness of about 300 Å to about 5,000 Å.

4. The method of claim 1, wherein the stepped portion is formed to a height of not less than 200 Å.

5. The method of claim 1, wherein the stepped portion is formed at a portion of the mask layer in a scribe lane region of the substrate.

6. The method of claim 1, wherein the stepped portion is formed at a portion of the mask layer in a device region of the substrate.

7. The method of claim 1, prior to forming the stepped portion, further comprising forming a well in a device region of the substrate.

8. The method of claim 7, wherein forming the well comprises implanting impurities into the device region of the substrate.

9. The method of claim 1, after forming the stepped portion, further comprising forming a well in a device region of the substrate.

10. The method of claim 9, wherein forming the well comprises:
forming a second photoresist pattern on the substrate; and
implanting impurities into the device region of the substrate using the second photoresist pattern as an ion implantation mask.

11. The method of claim 1, further comprising:
etching the mask layer and the substrate using the photoresist pattern as an etching mask to form a trench; and
filling the trench with an isolation layer for defining an active region of the substrate.

12. A method of manufacturing a semiconductor device, comprising:
implanting first impurities of a second conductivity type into a substrate having a device region and a scribe lane region to form a first well, the substrate being a first conductivity type different from the second conductivity type;
forming a mask layer on the substrate having the first well;
forming a first photoresist pattern on the mask layer, the first photoresist pattern partially exposing portions of the mask layer on the first region of the device region, and the scribe lane region;
partially etching the mask layer using the first photoresist pattern as an etching mask to form a first stepped portion of the mask layer in the first region of the device region, and a second stepped portion of the mask layer in the scribe lane region;
implanting second impurities of the first conductivity type into the first region using the first photoresist pattern as an ion implantation mask to form a second well;
removing the first photoresist pattern; and
forming a second photoresist pattern for forming an active region of the device region using the second stepped portion as an alignment mark.

13. The method of claim 12, prior to forming the mask layer, further comprising forming a pad oxide layer on the substrate.

14. The method of claim 12, wherein the mask layer comprises silicon nitride.

15. The method of claim 12, wherein the mask layer is formed to a thickness of about 300 Å to about 5,000 Å.

16. The method of claim 12, wherein the second stepped portion has a height of not less than 200 Å.

17. The method of claim 12, wherein the first well has a junction depth of about 1 μm to about 12 μm from a surface of the substrate.

18. The method of claim 12, prior to forming the second photoresist pattern, further comprising:
forming a third photoresist pattern using the second stepped portion as an alignment mark, the third photoresist pattern partially exposing a portion of the mask layer in a second region of the device region;
implanting third impurities of the first conductivity type into the second region using the third photoresist pattern as an ion implantation mask to form a third well; and
removing the third photoresist pattern.

19. The method of claim 18, wherein the third well has a junction depth of about 1 μm to about 12 μm from a surface of the substrate, the junction depth of the third well being shallower than that of the first well.

20. The method of claim 12, further comprising:
etching the mask layer and the substrate using the second photoresist pattern as an etching mask to form a trench; and
filling the trench with an isolation layer for defining an active region of the substrate.
